(19) United States
(12) Patent Application Publication
(10) Pub. No.: US 2015/0076626 A1
(43) Pub. Date: Mar. 19, 2015

(54) ELECTRONIC DEVICE

(71) Applicant: KABUSHIKI KAISHA TOSHIBA, Tokyo (JP)

(72) Inventor: Naofumi NAKAMURA, Tokyo (JP)

(21) Appl. No.: 14/210,218

(22) Filed: Mar. 13, 2014

(30) Foreign Application Priority Data
Sep. 13, 2013 (JP) 2013-190905

(51) Int. Cl. B81C 1/00; H01G 5/16; B81B 3/00

(52) U.S. Cl. CPC B81C 1/00793; B81B 3/0021; B81B 3/0089; H01G 5/16; B81B 2203/0118; B81B 2203/053; B81C 2201/053
USPC 257/415; 438/52

(57) ABSTRACT

According to one embodiment, an electronic device includes a substrate, a first electrode provided stationary above the substrate and used for a variable capacitor, a second electrode provided movable above or below the first electrode and used for the variable capacitor, a first protective insulation film provided on a first surface of the first electrode, the first surface facing the second electrode, and a second protective insulation film provided on a second surface of the second electrode, the second surface facing the first electrode.

### CROSS-REFERENCE TO RELATED APPLICATIONS

This application is based upon and claims the benefit of priority from Japanese Patent Application No. 2013-190905, filed Sep. 13, 2013, the entire contents of which are incorporated herein by reference.

### FIELD

Embodiments described herein relate generally to an electronic device.

### BACKGROUND

A micro electro mechanical system (MEMS) element with a variable capacitor formed on a semiconductor substrate has been proposed.

In this system, however, if the variable capacitor is formed of an easily-oxidizable metal, such as aluminum, the surfaces of electrodes may be ununiformly oxidized to thereby produce a metal oxide, with the result that even if, for example, two electrodes are attempted to be tightly attached to each other, this cannot be realized because of the produced metal oxide. Since MEMS elements are fine elements, the capacitance of the variable capacitor is hard to accurately control if such a problem as the above occurs. The metal oxide will also involve a problem associated with reliability that an oxide film formed on the electrode may peel off.

There is a demand for an electronic device with a variable capacitor that includes electrodes whose surface oxidation is controllable.

### BRIEF DESCRIPTION OF THE DRAWINGS

FIG. 1 is a schematic cross-sectional view showing part of a method of manufacturing an electronic device according to a first embodiment;

FIG. 2 is a schematic cross-sectional view showing part of the method of manufacturing the electronic device according to the first embodiment;

FIG. 3 is a schematic cross-sectional view showing part of the method of manufacturing the electronic device according to the first embodiment;

FIG. 4 is a schematic cross-sectional view showing part of the method of manufacturing the electronic device according to the first embodiment;

FIG. 5 is a schematic cross-sectional view showing part of the method of manufacturing the electronic device according to the first embodiment;

FIG. 6 is a schematic cross-sectional view showing part of the method of manufacturing the electronic device according to the first embodiment;

FIG. 7 is a schematic cross-sectional view showing part of the method of manufacturing the electronic device according to the first embodiment;

FIG. 8 is a schematic cross-sectional view showing part of the method of manufacturing the electronic device according to the first embodiment;

FIG. 9 is a schematic plan view showing the positional relationship between the structural elements of the electronic device according to the first embodiment;

FIG. 10 is a schematic plan view showing a modification of the positional relationship between the structural elements of the electronic device of the first embodiment;

FIG. 11 is a schematic plan view showing another modification of the positional relationship between the structural elements of the electronic device of the first embodiment;

FIG. 12 is a schematic cross-sectional view of an electronic device according to a modification of the first embodiment;

FIG. 13 is a schematic cross-sectional view of an electronic device according to a second embodiment;

FIG. 14 is a schematic cross-sectional view showing part of a method of manufacturing the electronic device according to the second embodiment; and

FIG. 15 is a schematic cross-sectional view of an electronic device according to a modification of the first embodiment.

### DETAILED DESCRIPTION

In general, according to one embodiment, an electronic device includes: a substrate; a first electrode provided stationary above the substrate and used for a variable capacitor; a second electrode provided movable above or below the first electrode and used for the variable capacitor; a first protective insulation film provided on a first surface of the first electrode, the first surface facing the second electrode; and a second protective insulation film provided on a second surface of the second electrode, the second surface facing the first electrode.

Embodiments will be described with reference to the accompanying drawings.

### First Embodiment

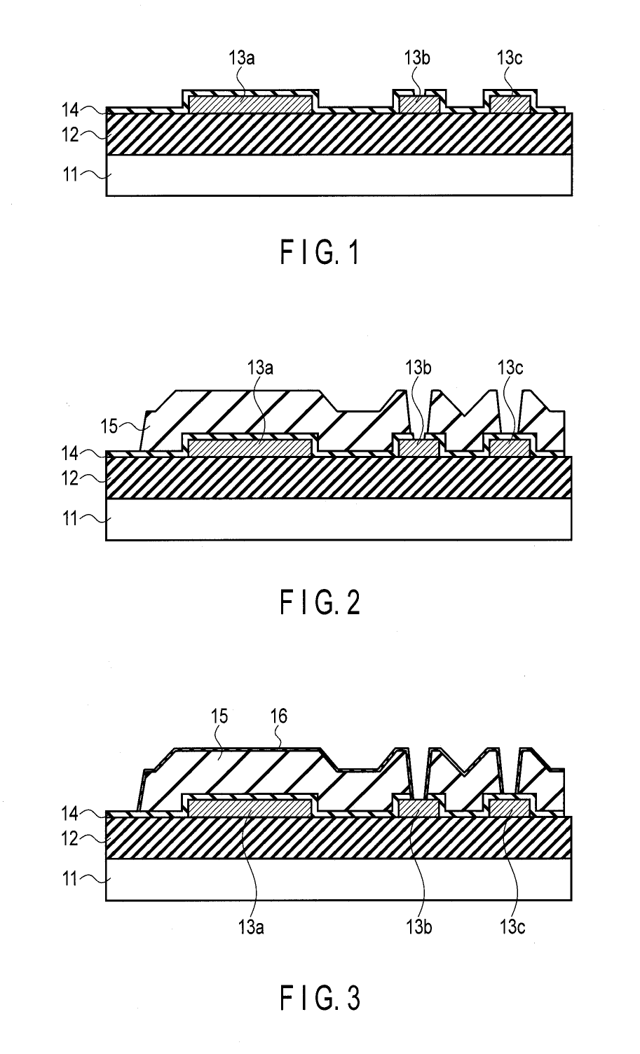

FIGS. 1 to 8 schematically show a method of manufacturing an electronic device according to a first embodiment.

Firstly, as shown in FIG. 1, a first electrode 13a for a variable capacitor, a lower pad 13b, and a lower electrode 13c for an MIM capacitor are formed above a semiconductor substrate 11. More specifically, an underlying insulation film 12 formed of, for example, a silicon oxide is formed on a semiconductor substrate 11. On the semiconductor substrate 11, elements, such as transistors, may be formed. Subsequently, an aluminum (Al) film with a thickness of approx. several hundreds nm to several μm is formed as a metal film on the underlying insulation film 12 by sputtering. This metal film is patterned by photolithography and etching, thereby forming a stationary first electrode 13a for the variable capacitor. During this patterning, the lower pad 13b, and the lower electrode 13c for the MIM capacitor are also formed. The etching may be reactive ion etching or wet etching.

Subsequently, a first protective insulation film 14 is formed on the first electrode 13a, the lower pad 13b, and the lower electrode 13c for the MIM capacitor, thereby covering them. More specifically, a silicon nitride (SiN) film with a thickness of approx. several hundreds nm to several μm is formed as the first protective insulation film 14 by chemical vapor deposition (CVD). In general, the first protective insulation film 14 is formed of a material containing silicon (Si), and at least nitrogen (N) or oxygen (O). Accordingly, a silicon oxide (SiO) film or a silicon oxynitride (SiON) film can be used as the first protective insulation film 14. The first protective insulation film 14 can prevent an oxide of an electrode metal (e.g., a metal oxide such as alumina) from being formed on the first electrode 13a during a high-temperature thermal treatment performed later.

Thereafter, the first protective insulation film 14 is patterned using photolithography and RIE to form an opening reaching the lower pad 13b.

After that, as shown in FIG. 2, a first sacrifice film 15 is formed on the first protective insulation film 14. An organic material (such as polyimide) film with a thickness of approx. several hundreds nm to several μm can be used as the first sacrifice film 15. Subsequently, the first sacrifice film 15 is patterned to form, for example, openings. More specifically, the first sacrifice film 15 can be patterned by coating the film 15 with an organic material film having photosensitivity, and then exposing the resultant structure to light and developing the exposed structure. Alternatively, the first sacrifice film 15 may be patterned by etching the same using a patterned photoresist formed thereon as a mask. Yet alternatively, the first sacrifice film 15 may be patterned using a predetermined insulation film as a hard mask.

After that, as shown in FIG. 3, a second protective insulation film 16 is formed on the first sacrifice film 15. More specifically, a silicon nitride (SiN) film with a thickness of approx. several nm to several hundreds nm is formed as the second protective insulation film 16 by CVD. In general, the second protective insulation film 16 is formed of a material containing silicon (Si), and at least nitrogen (N) or oxygen (O). Accordingly, a silicon oxide (SiO) film or a silicon oxynitride (SiON) film can be used as the second protective insulation film 16. Subsequently, the second protective insulation film 16 is patterned to form, for example, openings by photolithography and RIE.

The second protective insulation film 16 is formed sufficiently thinner than the first protective insulation film 14. For instance, the thickness of the second protective insulation film 16 is set to approx. 1/10 or less of that of the first protective insulation film 14. Further, the second protective insulation film 16 is formed sufficiently thinner than a second electrode 17a, described later. For instance, the thickness of the second protective insulation film 16 is set to approx. 1/10 or less of that of the second electrode 17a.

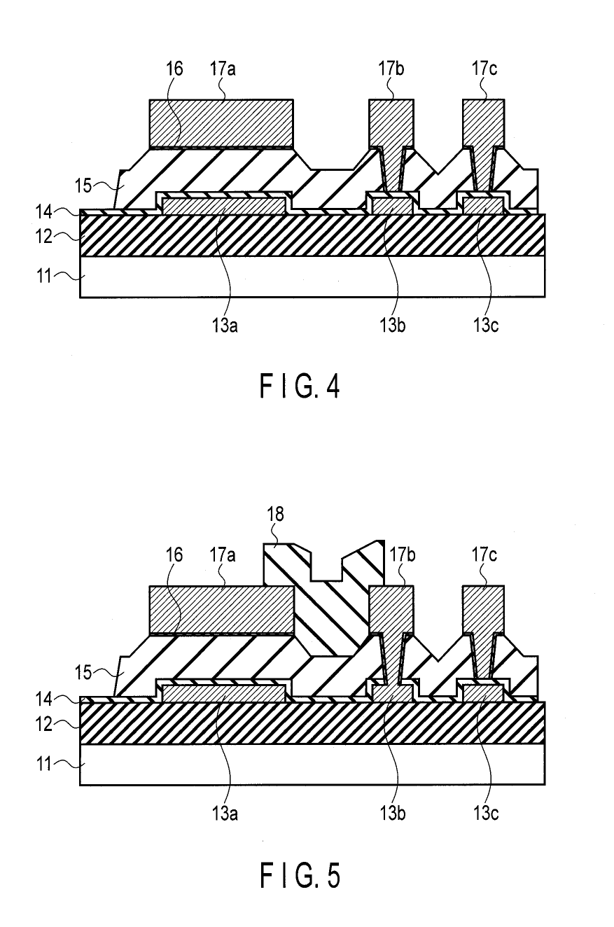

Subsequently, as shown in FIG. 4, the second electrode 17a for the variable capacitor is formed on the second protective insulation film 16. At this time, an upper pad 17b, and an upper electrode 17c for the MIM capacitor, are also formed. More specifically, an aluminum (Al) film with a thickness of approx. several hundreds nm to several μm is formed on the second protective insulation film 16. This metal film is patterned using photolithography and etching, thereby forming the second electrode 17a (which is movable) for the variable capacitor, the upper pad 17b, and the upper electrode 17c for the MIM capacitor. As the etching, reactive ion etching (RIE) or wet etching may be used. During this etching, the second protective insulation film 16 may be etched continuously. If a silicon nitride film is used as the second protective insulation film 16, this film can be removed by RIE using CF₄ or chemical dry etching (CDE).

Since the second protective insulation film 16 is formed under the second electrode 17a, the surface of the second electrode 17a can be prevented from being coated with an oxide (e.g., a metal oxide such as alumina) of the electrode metal when a high-temperature thermal treatment is performed later.

After that, as shown in FIG. 5, a connecting section 18 is formed to connect the second electrode 17a to the upper pad 17b. More specifically, the connecting section 18 is provided by forming a silicon nitride film with a thickness of approx. several hundreds nm to several μm by CVD, and then patterning the film. The connecting section 18 functions as part of a spring for the second electrode (movable electrode) 17a. The connecting section 18 may be formed of an insulator or a conductor of, for example, a metal.

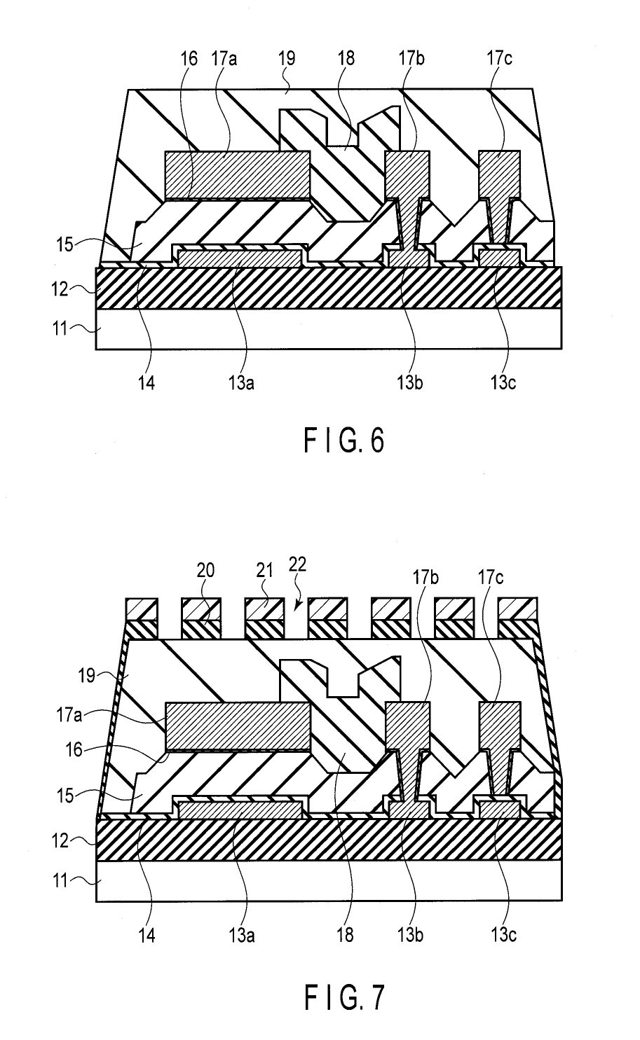

Thereafter, as shown in FIG. 6, a second sacrifice film 19 is formed to cover a structure including the second electrode 17a and other elements. More specifically, the second sacrifice film 19 may be formed of an organic material, such as polyimide. The second sacrifice film 19 is then patterned. Specifically, the second sacrifice film 19 can be patterned by etching using, as a mask, a photoresist pattern formed on the second sacrifice film 19. Alternatively, the second sacrifice film 19 may be patterned by coating this film with an organic material having photosensitivity, then exposing the resultant structure to light, and developing the exposed structure.

Subsequently, as shown in FIG. 7, a cover insulation film 20 for covering the second sacrifice film 19 is formed. Specifically, an insulation film, such as a silicon oxide film, is formed as the cover insulation film 20 by plasma CVD. On the cover insulation film 20, a patterned photoresist 21 is formed by photolithography. Using the patterned photoresist 21 as a mask, the cover insulation film 20 is etched to form therein a plurality of openings 22.

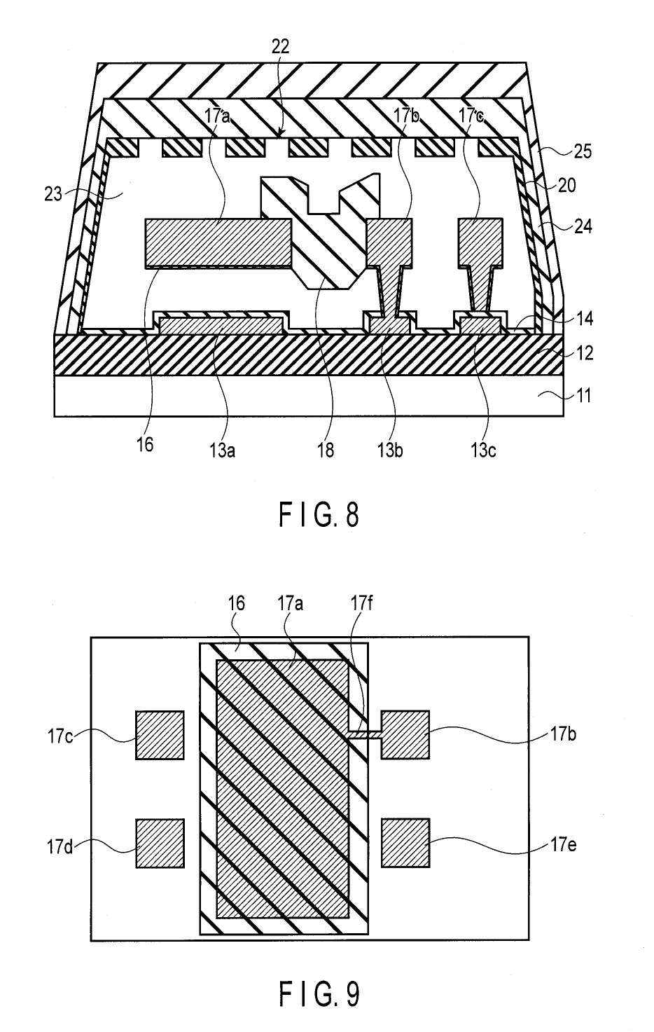

Thereafter, as shown in FIG. 8, the first sacrifice film 15 and the second sacrifice film 19 are removed. Specifically, these films are removed by ashing using oxygen (O₂). Through the openings 22 formed in the process step of FIG. 7, oxygen is introduced into the cover insulation film 20 to thereby remove the first sacrifice film 15 and the second sacrifice film 19. By this ashing, the patterned photoresist 21 is simultaneously removed, whereby a cavity 23 is formed within the cover insulation film 20.

Subsequently, an organic insulation film 24 is formed to cover the cover insulation film 20. An inorganic insulation film 25 is formed on the organic insulation film 24. As the organic insulation film 24, a UV-curable epoxy resin film, for example, can be used. As the inorganic insulation film 25, a silicon nitride film, for example, can be used. By thus forming the organic insulation film 24 and the inorganic insulation film 25, the openings 22 are sealed. The organic insulation film 24 can pass therethrough harmful gases in the cavity 23 to exhaust them. Thus, the organic insulation film 24 has a function of adjusting the atmosphere in the cavity 23. The inorganic insulation film 25 suppresses entering of harmful gasses, such as water vapor, into the cavity 23 through the organic insulation film 24.

An MEMS element having a variable capacitor is formed as described above. Namely, an electronic device is formed which comprises the first electrode 13a provided stationary above the semiconductor substrate 11 and used for a variable capacitor, the second electrode 17a provided movable above or below the first electrode 13a and used for the variable capacitor, the first protective insulation film 14 provided on the first surface of the first electrode 13a, the first surface facing the second electrode 17a, and the second protective insulation film 16 provided on the second surface of the second electrode 17a, the second surface facing the first electrode 13a.

As shown in FIG. 8, the first electrode (stationary electrode) 13a and the second electrode (movable electrode) 17a oppose each other, and provide a variable capacitor. The second electrode 17a is connected to the upper pad 17b via the connecting section 18 and supported by the upper pad 17b via the connecting section 18. When a desired voltage has been applied to the second electrode 17a, an electrostatic force is exerted between the first electrode 13a and the second electrode 17a to vary the position of the second electrode 17a. As a result, the distance between the first and second electrodes 13a and 17a varies to vary the capacitance of the variable capacitor.

FIG. 9 is a schematic plan view showing the positional relationship between the structural elements of the electronic device according to the first embodiment. The plan view of FIG. 9 merely schematically shows the positional relationship between the structural elements, and hence does not correspond to the cross-sectional views of FIGS. 1 to 8.

As shown in FIG. 9, the upper pad 17b, the upper electrode 17c for the MIM capacitor, a dummy electrode (dummy pad) 17d and a dummy electrode (dummy pad) 17e are provided outside the second electrode (movable electrode) 17a. The second electrode (movable electrode) 17a is connected to the upper pad 17b by a bias line 17f.

The second protective insulation film 16 protects the second electrode 17a. Accordingly, the pattern of the second protective insulation film 16 is substantially identical to or includes that of the second electrode 17a. In the example of FIG. 9, the pattern of the second protective insulation film 16 includes that of the second electrode 17a.

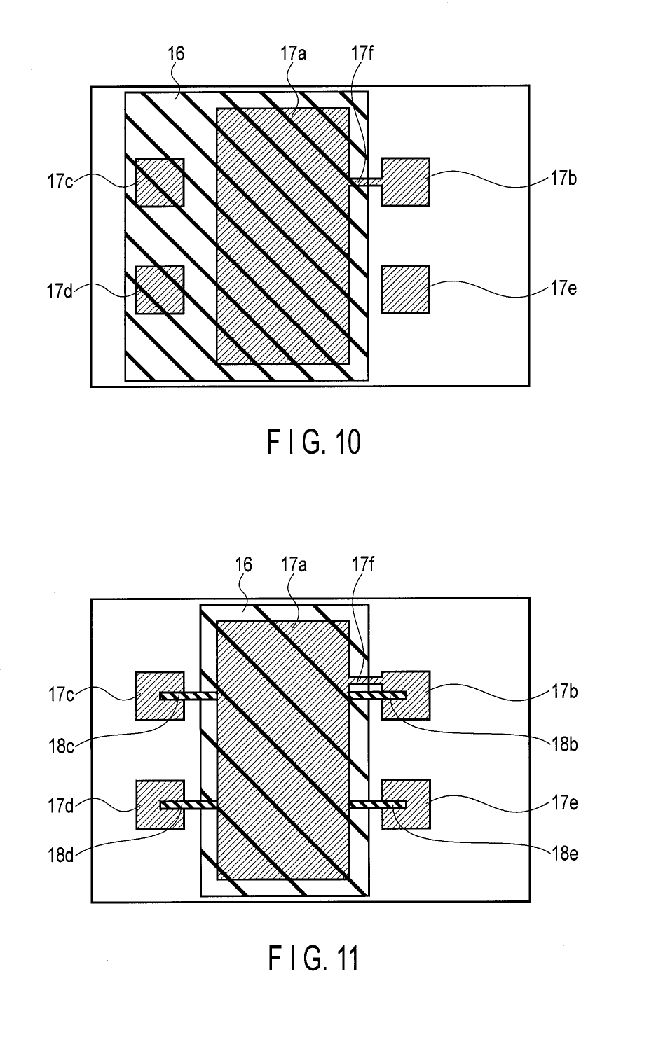

FIG. 10 is a schematic plan view showing a modification of the positional relationship between the structural elements of the electronic device of the first embodiment. In the example of FIG. 10, the pattern of the second protective insulation film 16 includes that of the upper electrode 17c for the MIM capacitor, and that of the dummy electrode (dummy pad) 17d. The other basic structure is similar to that shown in FIG. 9, and therefore explanation thereof is omitted.

FIG. 11 is a schematic plan view showing another modification of the positional relationship between the structural elements of the electronic device of the first embodiment. FIG. 11 also shows the positional relationship between connecting sections 18b, 18c, 18d and 18e. The other basic structure is similar to that shown in FIG. 9, and therefore explanation thereof is omitted.

As described above, in the first embodiment, the first protective insulation film 14 is provided on the first electrode 13a of the variable capacitor, and the second protective insulation film 16 is provided on the second electrode 17a. In other words, the first electrode 13a is covered with the first protective insulation film 14, and the second electrode 17a is covered with the second protective insulation film 16. Thus, the first and second electrodes 13a and 17a are protected by the first and second protective insulation films 14 and 16, respectively. As a result, oxidation (e.g., ununiform oxidation) of the surfaces of the first and second electrodes 13a and 17a can be suppressed.

As aforementioned, if the electrodes of the variable capacitor are formed of an easily-oxidizable metal, such as aluminum, the surfaces of the electrodes may well be ununiformly oxidized. For instance, in a high-temperature process, such as a curing step of the sacrifice films 15 and 19, the surfaces of the first and second electrodes 13a and 17a may be oxidized. When an ununiform oxide film has been formed on the first electrode 13a or the second electrode 17a, even if, for example, the two electrodes are attempted to be tightly attached to each other, this cannot be realized. As a result, it becomes difficult to accurately control the capacitance of the variable capacitor. Further, a problem in reliability that an oxide film formed on an electrode peels off may also occur.

In the first embodiment, the first protective insulation film 14 and the second protective insulation film 16 can suppress oxidation of the surfaces of the first and second electrodes 13a and 17a. Consequently, the embodiment can provide a highly reliable electronic device.

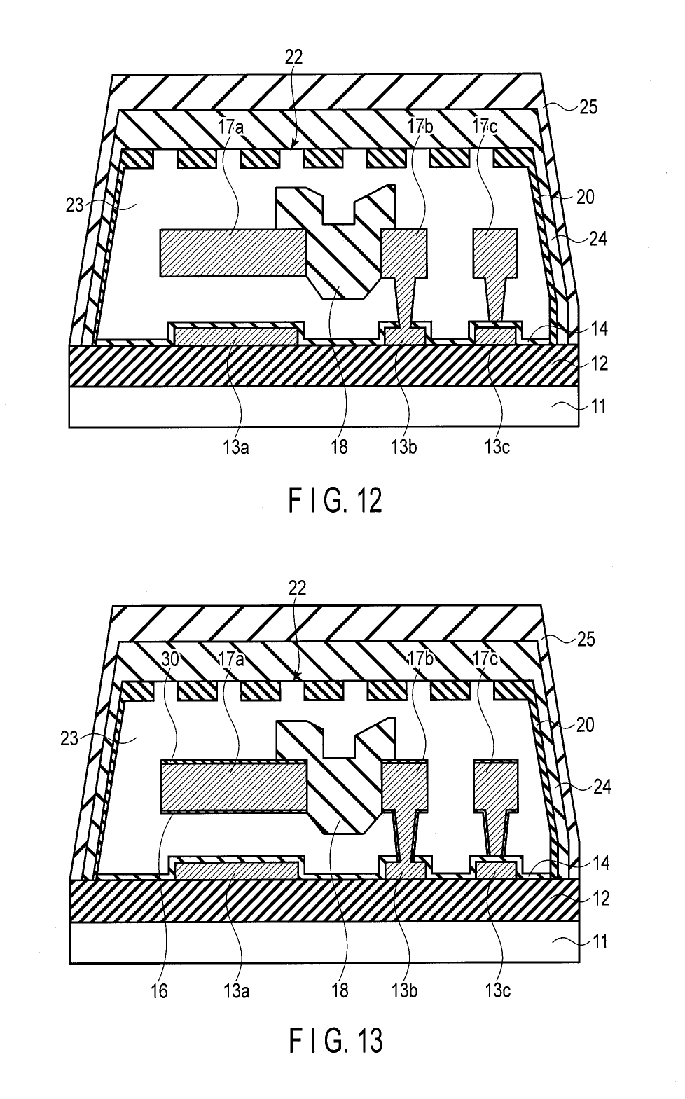

FIG. 12 is a cross-sectional view of a modification of the first embodiment.

In the modification, the second protective insulation film 16 is removed after the process step of FIG. 8. In general, no special high-temperature treatment is performed after removing the sacrifice films 15 and 19 in the process step of FIG. 8. Therefore, a problem that the surface of the second electrode 17a is oxidized little occurs even if the second protective insulation film 16 is removed. Because of this, the second protective insulation film 16 may be removed as shown in FIG. 12.

Further, note that when the second protective insulation film 16 is removed by etching, the first protective insulation film 14 is simultaneously etched. Since, however, the first protective insulation film 14 is sufficiently thicker than the second protective insulation film 16, it is not completely removed but part of the same remains.

Yet further, the second protective insulation film 16 may be removed when removing the sacrifice films 15 and 19 in the process step of FIG. 8.

### Second Embodiment

A second embodiment will now be described. Since the second embodiment is similar to the first embodiment in basic structure and basic manufacturing method, only different matters will be described.

FIG. 13 is a schematic cross-sectional view of an electronic device according to the second embodiment. In the second embodiment, elements similar to those shown in FIGS. 1 to 8 (first embodiment) denoted by corresponding reference numbers, and no detailed description will be given thereof.

As shown in FIG. 13, the second embodiment incorporates a third protective insulation film 30 provided on the upper surface (third surface) of the second electrode 17a opposite to the lower surface (second surface) thereof, in addition to the structure shown in FIG. 8.

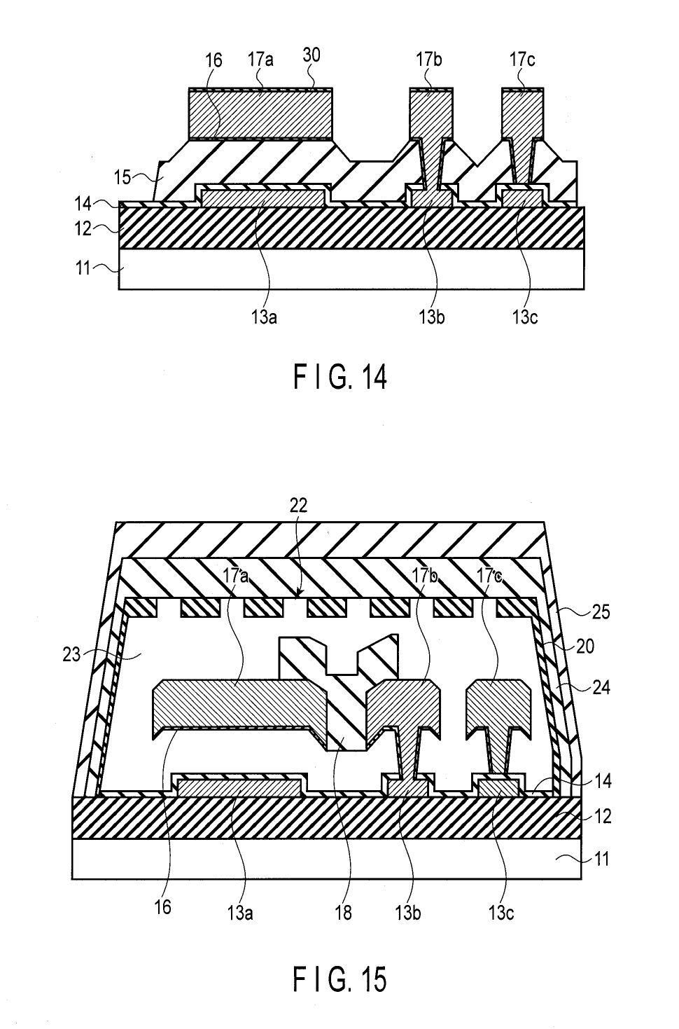

Referring to FIG. 14, a method of manufacturing the third protective insulation film 30 will be described.

In the second embodiment, the process step of FIG. 14 is performed after the process step of FIG. 3. In the process step of FIG. 14, after a metal film (aluminum film) for forming, for example, the second electrode 17a is formed, the third protective insulation film 30 is formed on the metal film before the metal film is patterned. More specifically, on the metal film, a silicon nitride (SiN) film with a thickness of approx. several nm to several hundreds nm is formed as the third protective insulation film 30 by CVD. In general, the third protective insulation film 30 is formed of a material containing silicon (Si), and at least one of nitrogen (N) and oxygen (O). Accordingly, the third protective insulation film 30 may be formed of silicon oxide (SiO) or silicon oxynitride (SiON).

Subsequently, the third protective insulation film 30, the metal film and the second protective insulation film 16 are patterned by photolithography and etching to form, for example, openings. As the etching, RIE, CDE, wet etching, etc., can be used.

Thus, such a structure as shown in FIG. 14 is formed. After that, the same steps as those shown in FIGS. 5 to 8 (first embodiment) are performed to obtain an electronic device having the variable capacitor shown in FIG. 13.

As in the modification of the first embodiment shown in FIG. 12, the second protective insulation film 16 may be removed after the process step of FIG. 13. When the protective insulation film 16 is removed, the third protective insulation film 30 may be simultaneously removed. Further, when the sacrifice films 15 and 19 are removed in the process step of FIG. 13, the second and third protective insulation films 16 and 30 may also be removed.

In the second embodiment, oxidation of the surfaces of the first and second electrodes 13a and 17a can be suppressed by providing the first and second protective insulation films 14 and 16, as in the first embodiment. Further, since the second embodiment also employs the third protective insulation film 30, oxidation of the opposite surface of the second electrode 17a can also be suppressed.

Further, although in the above-described first and second embodiments, the second electrode 17a, the upper pad 17b and the upper electrode 17c are flat, they may have their ends downwardly bent as shown in FIG. 15. If the ends of the second electrode 17a are bent outside the first electrode 13a, there is no problem unless the ends of the second electrode 17a are in contact with the ground layer (e.g., the protective insulation film 14), when the second electrode 17a is in the down state position. Thus, the second electrode 17a may have a shape that will be engaged with the first electrode 13a.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a substrate;
a first electrode provided stationary above the substrate and used for a variable capacitor;
a second electrode provided movable above or below the first electrode and used for the variable capacitor;
a first protective insulation film provided on a first surface of the first electrode, the first surface facing the second electrode; and
a second protective insulation film provided on a second surface of the second electrode, the second surface facing the first electrode.

2. The electronic device of claim 1, further comprising a third protective insulation film provided on a third surface of the second electrode opposite to the second surface.

3. The electronic device of claim 1, wherein each of the first and second protective insulation films is formed of a material containing silicon (Si) and at least one of nitrogen (N) and oxygen (O).

4. The electronic device of claim 1, wherein the second electrode is movable in a cavity formed by a first film provided above the second electrode and having an opening and a second film provided on the first film.

5. The electronic device of claim 1, wherein the first electrode is formed of a material containing aluminum (Al) as a main component.

6. The electronic device of claim 1, wherein the second electrode is formed of a material containing aluminum (Al) as a main component.

7. The electronic device of claim 1, wherein the second protective insulation film is thinner than the first protective insulation film.

8. The electronic device of claim 1, wherein the second protective insulation film has a thickness 1/10 or less of a thickness of the first protective insulation film.

9. The electronic device of claim 1, wherein the first protective insulation film covers the entire first surface of the first electrode.

10. The electronic device of claim 1, wherein the second protective insulation film covers the entire second surface of the second electrode.

11. The electronic device of claim 1, wherein the second electrode has ends downwardly bent.

12. A method of manufacturing an electronic device, comprising:
forming, above a substrate, a first electrode used for a variable capacitor;
forming a first protective insulation film on the first electrode;
forming a first sacrifice film on the first protective insulation film;
forming a second protective insulation film on the first sacrifice film;
forming, on the second protective insulation film, a second electrode used for the variable capacitor;
forming a second sacrifice film covering the second electrode;
forming a cover insulation film covering the second sacrifice film; and
removing the first and second sacrifice films.

13. The method of claim 12, further comprising forming a third protective insulation film on a conductive film for the second electrode.

14. The method of claim 12, wherein each of the first and second protective insulation films is formed of a material containing silicon (Si) and at least one of nitrogen (N) and oxygen (O).

15. The method of claim 12, wherein a cavity is formed by removing the first and second sacrifice films.

16. The method of claim 12, wherein the first electrode is formed of a material containing aluminum (Al) as a main component.

17. The method of claim 12, wherein the second electrode is formed of a material containing aluminum (Al) as a main component.

18. The method of claim 12, wherein the second protective insulation film is thinner than the first protective insulation film.

19. The method of claim 12, wherein the second protective insulation film has a thickness 1/10 or less of a thickness of the first protective insulation film.

20. The method of claim 12, further comprising removing the second protective insulation film after or when removing the first and second sacrifice films.
